(19) United States
(12) Patent Application Publication
(10) Pub. No.: US 2013/0207094 A1
(43) Pub. Date: Aug. 15, 2013

(54) METHOD FOR PROVIDING ELECTRICAL CONNECTION(S) IN AN ENCAPSULATED ORGANIC LIGHT-EMITTING DIODE DEVICE, AND SUCH AN OLED DEVICE

(71) Applicant: Svetoslav Tchakarov, Sceaux (FR)

(72) Inventor: Svetoslav Tchakarov, Sceaux (FR)

(73) Assignee: SAINT-GOBAIN GLASS FRANCE, Courbevoie (FR)

(21) Appl. No.: 13/876,297

(22) PCT Filed: Sep. 23, 2011
(86) PCT No.: PCT/FR2011/052209

§ 371 Date: Apr. 30, 2013

(30) Foreign Application Priority Data
Sep. 27, 2010 (FR) 1057746

(51) Int. Cl. H01L 51/52

(52) U.S. Cl. CPC H01L 51/5237
USPC 257/40; 438/26; 257/99

(57) ABSTRACT

A process for manufacturing an encapsulated OLED device, which includes, after encapsulation of the device, a step of ultrasonic soldering at a first edge of the lower electrode, forming a lower electrical connection zone with a solder pad extending from the encapsulation surface as far at least as the surface of the lower electrode, and/or a step of ultrasonic soldering in an upper electrical connection zone with a solder pad extending from the encapsulation surface as far at least as the surface of the upper electrode.

The invention relates to a process for making one or more electrical connections to an organic light-emitting diode containing encapsulated device, and to such a device.

An organic light-emitting diode (OLED) containing device conventionally comprises:
a glass substrate;
a lower electrode made of one or more electroconductive layers;
an organic light-emitting system; and
an upper electrode made of one or more electroconductive layers.

As is known, OLEDs are electronic components that are very sensitive to oxygen, liquid water and water vapor. Thus, OLEDs are furthermore provided with one or more encapsulation layers covering the organic light-emitting system.

Moreover, OLEDs are conventionally provided with conductive electrical connection elements in order to supply power to the electrodes.

Currently, this connection is made to exposed parts of the electrodes, parts that are not covered by the encapsulation.

Thus, patent EP 030 779 39 describes an OLED lamp (see FIG. 2) comprising:
a substrate;
a first electrode;
an organic light-emitting system partially covering the lower electrode and leaving thus exposed a portion of the first electrode at a first substrate edge (for the lower electrical connection);
a second electrode covering the organic light-emitting system and extending to a second substrate edge opposite the first substrate edge (for the upper electrical connection);
a layer-based encapsulation, partially covering the upper electrode, and leaving exposed, in part, the first and second edges for the electrical connections.

Thus, to allow these connections to be made, the encapsulation layers are deposited through a mask protecting the specified connecting zones, thereby making the process more complicated and/or laborious (mask placement, removal, etc.).

In addition, in shadowed regions (mask edges) defects may appear that compromise the encapsulation.

Document WO 2008/103558 describes an OLED device (in relation to FIG. 4c) with an encapsulating film surrounding the entire device and comprising holes (or “contact vias”) for connecting elements (or “leads”) to the electrodes, the holes being filled with adhesive conductors, silver containing ink, or solder.

It is even possible to simplify the wiring and/or improve the electrical reliability of the OLED device obtained.

The objective of the invention is thus to provide an organic light-emitting diode containing device encapsulated by one or more layers, and with wiring that is simpler and more reliable, especially an OLED device that is more compatible with industrial requirements (production yield, ease of production, etc.) even for large areas.

For this purpose, the invention firstly provides a process for making one or more electrical connections to an organic light-emitting diode containing encapsulated device comprising, in this order:
a dielectric substrate, especially a transparent dielectric substrate, especially a dielectric substrate made of mineral glass or of plastic;
a first optionally transparent electrode, called the lower electrode, based on one or more electroconductive layers;
an organic light-emitting system based on one or more organic light-emitting layers, located on the lower electrode;
a second optionally transparent electrode, called the upper electrode, for example based on one or more electroconductive layers, located on the organic light-emitting system and (partially) extending onto an adjacent zone that is electrically isolated from the lower electrode (bare zone, optionally covered by said one or more electroconductive lower electrode layers, separated by structuring from this electrode);
an electrically insulating dielectric encapsulation based on one or more optionally transparent layers, covering (therefore entirely on) the upper electrode, the organic light-emitting system and the lower electrode, and preferably also covering the edge face of at least the organic light-emitting system, and even more preferably covering the edge face of the lower electrode and/or the edge face of the upper electrode).

The process furthermore comprises, after encapsulation of the device:
a step of ultrasonic soldering (also called US soldering) at a first edge of the lower electrode, forming a lower electrical connection zone, the solder forming, via local deterioration, a solder pad extending (especially substantially vertically) from the encapsulation surface as far at least as the surface of the lower electrode (preferably the main surface or even the surface of the edge face); and/or
a step of ultrasonic soldering (also called US soldering) in the adjacent zone, which is electroconductive (electroconductive layer(s), etc.)—adjacent zone, optionally surmounted, at least in one area, by the upper electrode, and for example adjacent zone opposite an edge distinct from the first edge—and forms an upper electrical connection zone, the solder forming, via local deterioration, a solder pad extending (especially substantially vertically) from the encapsulation surface as far at least as the surface of the upper electrode (preferably the main surface or even the surface of the edge face).

This process is simple and very inexpensive to implement. It makes it possible to define and incorporate, simply and economically, the lower connection zone and/or the upper connection zone in the encapsulated OLED device without making holes in the encapsulation beforehand, these holes conventionally being produced by photolithography (using a mask) before deposition of the encapsulation.

The process according to the invention, by making steps of placing and removing a mask or masks redundant, saves labor and has a smaller number of steps that are production yield critical, while improving the reliability of these OLED devices over time.

The process according to the invention is also more tolerant of alignment errors. Since the connection is made a posteriori, the number of alignment errors, especially alignment relative to the mask aperture, is reduced.

Thus, firstly, the invention allows leakage current to be reduced by a substantial amount by limiting the risk of surface contamination by the mask-handling tool.

In addition, since the mask is often placed automatically in the deposition tool, additional investment related to this automatic control is required. The mask is also a device that can be reused many times but that requires a special cleaning procedure, which is unnecessary with the process according to the invention.

Moreover, sometimes, during the deposition steps for depositing the various layers, after the mask has been applied, the latter expands at a different rate to the substrate under the effect of heating, so much so that, during the application of the one or more electroconductive layers forming the upper electrode, the latter may make contact with the lower electrode, thus creating, by misalignment, a short-circuit of greater or lesser extent.

Next, during removal of the mask, the layers that were deposited on the latter have a tendency to disintegrate and then to redeposit on the multilayer in the form of dust, thus causing the OLED device to malfunction. For this reason, in order to prevent such a drawback, removal of the mask is conventionally accompanied by a suction, this operation thus requiring two operators.

The present invention furthermore gives designers greater freedom when designing OLED devices since the connection zones of these devices may be shaped and arranged on the electrodes depending on the desired illumination profile to be obtained.

During the US soldering (sometimes confused with ultrasonic welding) the one or more layers of the electrode in question, about a few nm to a few hundred nm in thickness, will also generally be (partially or completely) pierced. The solder and electrode are then electrically connected laterally, via the edges.

The application of the ultrasound is essential if the solder is to bond to the dielectric substrate, in particular when it is made of glass.

It may be envisioned to use separate methods to form the electrical connection zones of the two electrodes. However, it is preferable to use ultrasonic soldering for both electrodes.

The process according to the invention may furthermore make redundant production of internal current leads, i.e. leads under the encapsulation layer and adjacent the electrodes, such as described in document WO 2008/103558, or even production of current leads in an encapsulation-free border zone.

A known current lead used in OLEDs takes the form of a strip (busbar) on the electrode in question, serving to uniformly spread current, and especially comprising:
a metal layer, for example a 50 to 1000 nm-thick PVD-deposited Ni, NiCr, Al or Cu layer, which involves additional metallization and patterning steps; or
a screen-printed silver containing enamel layer about 10 μm to 100 μm in thickness, which involves a bake at at least 120° C.; or
an optionally adhesive electroconductive material, especially a foam, deposited by inkjet printing and containing silver or copper metal (nano) particles, which involves a bake at a temperature above 60° C.

This step of forming one or more current leads may be simplified. For example: the step of forming a current lead for the lower electrode, subjacent the encapsulation layer, may be coupled with (especially concomitant with) the step of forming the lower electrode, and comprise the deposition of one or more materials for the lower electrode.

Thus one or more current leads are produced with the very same deposition used to deposit the one or more materials for the lower electrode—especially a mesh electrode as, for example, described in document WO 2010/034944—as follows:
provision of a fissured mask in the lower electrode zone for deposition of the mesh electrode (through the fissures) and with at least one adjacent mask-free zone for forming a current lead, for example as strip;
deposition of the electrode material, especially a metal (silver, aluminum, etc.) layer in the electrode zone (forming a mesh) and in the current lead zone (forming an unapertured metal zone); and
removal of the mask.

This mesh electrode may furthermore be smoothed by filling the space in the cells of the mesh and by adding a smoothing electroconductive coating in the cells and over the strands of the mesh (optionally identical to the filling material), especially such as described in document WO 2009/071821.

Alternatively, or cumulatively, the connection process according to the invention may preferably be:
exempt from any steps of forming internal current leads, especially strip leads, for the lower electrode and/or for the upper electrode, i.e. exempt of any current leads subjacent the encapsulation layer (as yet unpierced by the solder), before said encapsulation; and/or
exempt from any steps of forming current leads, especially strip leads, in a (more peripheral, especially border) zone without said encapsulation layer, after said encapsulation.

Moreover, preferably, the solder for the lower electrical connection may be sufficiently extensive to spread current (therefore forming a partially external current lead zone for the lower electrode) and/or the solder for the upper electrical connection is sufficiently extensive to spread current (therefore forming a partially external current lead zone for the upper electrode).

The US soldering zone may be formed by one or more soldering points, especially along a given electrode edge, or may be continuous, forming a strip for example.

The upper connection zone (which is optionally a US soldering zone) may be an edge adjacent or opposite the lower connection zone (which is optionally a US soldering zone).

The US solder is generally an alloy solder, most often (mainly) a tin-based alloy solder.

Once the US soldering has been carried out, the electrode in question can be easily connected to an external connecting element. The electrical connection between the connection element and the electrode in question may be ensured simply by contact. However, apart from the fact that this type of electrical contact is far from perfect, this contact method risks perforation of the electrode, and therefore degradation of the functionality of the glazing unit, during use.

Also preferably, the process according to the invention may comprise connection of an external connecting element for the lower electrode especially by heating the encapsulated device in the lower electrical connection zone after the ultrasonic soldering or during the ultrasonic soldering for the lower electrical connection zone and/or it may comprise connection of an external connecting element for the upper electrode especially by heating the encapsulated device in the upper electrical connection zone after the ultrasonic soldering or during the ultrasonic soldering for the upper electrical connection zone.

It is thus possible to easily and reliably connect the electrode in question to an external connecting element (which, preferably, is flat and protrudes from the substrate).

The external electrical connection element is especially chosen from at least one of the following electrical connection means:
at least one electroconductive, for example metal, wire, for example made of copper, aluminum, steel, stainless steel, iron, tungsten, gold, or silver; and
at least one optionally (self)adhesive electroconductive strip, especially a metal strip such as a foil, for example between about 50 pm and 100 pm in thickness.

The external electrical connection means may be provided, on its surface, with a solder (tinned copper, etc.) in order to aid its attachment.

The OLED device according to the invention may:
emit from the substrate (bottom emission), in which case the lower electrode and the substrate are transparent and the upper electrode is reflective;
emit from the top (top emission), in which case the upper electrode is transparent and the lower electrode is reflective; or
emit both from the substrate and from the top, in which case the upper electrode and the lower electrode are both transparent.

In a first configuration, the lower connecting solder does not pass through the one or more materials of the upper electrode in the lower electrical connection zone (and preferably does not pass through the internal element connected, in particular, to current leads, in particular of the wire type).

For example, the deposition of the one or more layers for the upper electrode may leave exposed the first edge optionally coated with the one or more organic light-emitting layers, especially via masking of the first edge.

Therefore, a mask is used in deposition of the upper electrode, in particular if the deposition is a vacuum deposition, for example evaporation in which a magnetic mask (Ni, etc.), held by magnets on the opposite face of the substrate, may be used, in contrast to deposition by magnetron sputtering.

Such depositions are more easily produced if the upper electrode is reflective i.e. often thick, especially a monolayer, for example of aluminum.

In a second configuration, the lower connecting solder passes through the one or more materials of the upper electrode in the lower electrical connection zone.

For example, the layer deposition for the upper electrode covering said first edge (and the one or more subjacent organic layers), the process may comprise, preferably before the US soldering in the lower electrical connection zone and especially before encapsulation, a selective local structuring, without (post-) masking, in the zone of the first edge, which divides said layer deposition for the upper electrode into an electrically inactive zone and into said upper electrode (and optionally dividing the subjacent organic layers), this structuring optionally extending as far as the lower electrode (non-inclusively or at least partially in order to preserve its electroconductive function), and preferably the process comprises filling the structured zone with an insulating material.

This may especially be achieved by laser ablation, by adjusting the power (in order to control the ablation depth) and the wavelength depending on the absorption of the layers.

It is also possible to use chemical etching, especially chemical screen printing, or mechanical cutting.

In this first configuration, the lower electrode may especially be reflective, and the upper electrode transparent.

Moreover, the layer deposition for the, especially transparent, lower electrode, for example by magnetron sputtering, may cover the zone intended to be the adjacent zone, of upper connection.

The process may then comprise, before the layer deposition for the upper electrode (and preferably with the organic layer deposition) a local structuring of said one or more layers of the lower electrode (optionally of the organic layers) without (post-) masking:
by laser ablation (cutting), the wavelength and the power being-adjusted depending on the absorption of the layers, laser ablation being preferred when the lower electrode is not reflective (metal);
by chemical etching; or
by mechanical cutting.

Furthermore, the process may preferably comprise filling the zone thus structured (especially by screen printing) with an insulating material that is, in particular, thicker and that extends over one edge of the electrode.

Naturally, it may be preferable to choose to use, for the upper electrode, the same selective local structuring technique used for the local structuring of the lower electrode, laser cutting for example.

After the contacts have been fitted on the electrodes, the OLED device may be covered with an electrically insulating and/or mechanically protecting element that may be transparent if necessary.

For example, after the one or more US soldering steps, a lamination is carried out, if necessary, with an intermediate material (a thermoplastic sheet for example) and a counter substrate, especially a glass counter substrate.

The external electrical connection means may thus be incorporated on one side of a lamination interlayer.

By way of common lamination interlayers, mention may be made of flexible polyurethane (PU), a plasticizer-free thermoplastic such as ethylene vinyl acetate (EVA) or polyvinyl butyral (PVB), or a polyethylene acrylate copolymer, for example sold by DuPont under the name Butacite or sold by Solutia under the name Saflex. These plastics for example are between 0.2 mm and 1.1 mm in thickness, especially being between 0.38 and 0.76 mm in thickness.

By way of other plastic materials, polyolefins, such as polyethylene (PE), polypropylene (PP), PEN or PVC, or ionomer resins may be used.

The invention also relates to an organic light-emitting encapsulated device with one or more electrical connections, especially such as manufactured using the process described above, comprising, in this order:
a dielectric substrate, especially a transparent dielectric substrate;
a first, especially transparent, electrode, called the lower electrode, based on one or more electroconductive layers;
an organic light-emitting system based on one or more organic light-emitting layers, located on the lower electrode;
a second (optionally transparent) electrode, called the upper electrode, based on one or more electroconductive layers, located on the organic light-emitting system and (partially) extending onto an adjacent zone that is electrically isolated from the lower electrode (bare, optionally covered by one or more electroconductive lower electrode layers, separated by structuring);
an (electrically insulating) dielectric encapsulation based on one or more (transparent) layers, covering (therefore entirely on) the upper electrode, the organic light-emitting system and the lower electrode, and preferably also covering the lateral edges of at least the organic light-emitting system (and preferably of the lower electrode and/or upper electrode); and
an electrical connection, called the lower electrical connection, for the lower electrode, and an electrical connection, called the upper electrical connection, for the upper electrode, and furthermore comprising:
at a first edge of the lower electrode, a lower electrical connection zone formed from a solder pad (by US soldering) making contact with the lower electrode (preferably from the top though even via the edge face) and opening (substantially vertically) out of the encapsulation; and/or
in the adjacent zone, which is electroconductive and electrically isolated from the lower electrode, an upper electrical connection zone formed from solder (by US soldering), opening (substantially vertically) out of the encapsulation.

This solder pad makes contact with the upper electrode (preferably from the top though even via the edge face) or with the surface of the one or more adjacent electroconductive layers electrically connected with the upper electrode in said zone.

The OLED device may furthermore be envisioned with one or more of the following features:
the upper electrode covers the first edge of the lower electrode and a zone of selective electrical isolation is located between the lower electrical connection and the upper electrical connection, this zone separating the upper electrode, or even the subjacent organic layers, into two parts, the subjacent lower electrode being preserved (or sufficiently preserved);
the zone of selective electrical isolation is a cut, especially produced by laser cutting;
the upper electrode does not cover the first edge of the lower electrode;
the lower electrode is a thin-film multilayer comprising at least one thin silver-based film and the dielectric encapsulation also covers the edge face of the lower electrode in order to protect it;
the substrate is made of glass, especially mineral glass;
in the adjacent zone, the one or more electroconductive layers are identical to the one or more electroconductive layers of the lower electrode, and are electrically isolated by cutting, especially laser cutting; and/or
it comprises an external connecting element for the lower electrode connected, especially by soldering, to the solder pad and/or an external connecting element for the upper electrode connected, especially by soldering, to the solder pad.

The electrode may be obtained by a deposition or a succession of depositions carried out using a vacuum technique such as sputtering or optionally magnetron sputtering.

For a (semi)transparent electrode, any type of transparent electroconductive layer may be used, for example layers such as “TCOs” (transparent conductive oxides). The electrodes may especially be electroconductive layers chosen from metal oxides, especially the following materials:
doped tin oxide, especially doped with fluorine SnO₂:F or with antimony SnO₂:Sb (in the case of chemical vapor deposition “CVD”, tin organometallic or halide precursors associated with a fluorine precursor such as hydrofluoric acid or trifluoroacetic acid may be used);
doped zinc oxide, especially doped with aluminum ZnO:Al (in the case of chemical vapor deposition “CVD”, zinc and aluminum organometallic or halide precursors may be used) or with gallium ZnO:Ga;
or even doped indium oxide, especially doped with tin ITO (in the case of chemical vapor deposition “CVD”, tin and indium organometallic or halide precursors may be used), or zinc-doped indium oxide (IZO).

Metal layers called “TCCs” (for transparent conductive coatings) may also be used, for example made of Ag, Al, Pd, Cu, Pd, Pt, In, Mo, Au.

Lastly, use may be made of a silver containing multilayer: electrical layer(s)/Ag/dielectric layer(s)/Ag/dielectric layer(s), such as described in documents WO 2008/059185, WO 2009/083693.

For a reflective electrode, one or more metal layers “TCCs” (transparent conductive coatings), for example made of Ag, Al, Pd, Cu, Pd, Pt, In, Mo or Au, may be used.

The surfaces of the electrodes are not necessarily continuous.

The encapsulation produced more particularly allows the one or more silver layers to be protected from environmental corrosion.

Encapsulation layers, preferably having a total thickness larger. than 100 nm and smaller than 3 pm, may be chosen from mineral layers (Al₂O₃, Si₃N₄, SiO₂, AlN, etc.) optionally with addition of polymer layers (parylene, polyimide, etc.).

The lower electrode, if transparent, may be a mesh electrode, especially such as described in document WO 2008/132397 with, as has already been seen, preferably an unapertured border for the current lead.

Of course, the location of the lower connection zone, generally along one edge of the substrate (and/or of the active OLED zone) may vary and may especially be:
on a single edge;
on a first edge and on a second adjacent edge (continuously or discontinuously), especially at right angles;
on a first edge and on a second opposite edge.

Of course, the location of the upper connection zone, generally along one edge of the substrate (and/or of the active OLED zone) may vary and may especially be:
on a single edge;
on a first edge and on a second adjacent edge (continuously or discontinuously), especially at right angles;
on a first edge and on a second opposite edge.

Lastly, the upper connection zone may be on an edge adjacent or opposite the edge of the lower connection zone.

Furthermore, depending on the location of these connection zones, appropriate modifications are made to:
the location and the number of selective local structurings for the upper electrode;
the location and number of local structurings for the lower electrode; and/or
the number of electrical connections and US soldering operations.

The OLED device encapsulated according to the invention may furthermore be subdivided into a plurality of organic light-emitting zones, for example such as described in document WO 2008/119899.

The encapsulated OLED device according to the invention may then be equipped with:
a lower electrode that is discontinuous, thus forming at least one row of lower electrode zones, preferably some or all of the electrode zones being at least 3 cm in size in the direction of said row, the electrode zones of the row being, for example, spaced apart from one another by a distance called the intrarow distance, which is especially 0.5 mm or less;
an organic light-emitting system that is discontinuous, taking the form of light-emitting zones arranged on the lower electrode zones; and
an upper electrode that is discontinuous, taking the form of upper electrode zones arranged on the light-emitting zones, the encapsulation covering the entire device.

Each electrode zone may have a geometric shape (square, rectangle, circle, etc.) and may especially be unapertured or a mesh.

The electrodes zones within a row may have substantially the same shape and/or size. In the direction perpendicular to the row, the lower electrode zone may be any size, for example at least 3 cm or 5 cm in size, or even about 10 cm in size (10 cm or more).

The lower electrode may be formed from a single row of lower electrode zones, and, in the direction perpendicular to this row, the upper electrode and the light-emitting layer may be discontinuous in order to form a plurality of parallel rows. Etching of the lower electrode is then preferably carried out (one line) perpendicular to the orientation of the rows of upper electrodes. From one row to another, the zones may be shifted, for example so as to be staggered.

For series connection of the row of lower electrode zones, the light-emitting zones are shifted relative to the lower electrode zones in the direction of this row, and the upper electrode zones are shifted relative to the light-emitting zones in the direction of this row.

It will be recalled that, in series connection, the current passes from an upper electrode zone to the adjacent lower electrode zone.

This type of connection guarantees the uniformity of the illumination over large areas, a satisfactory fill factor, reliability, and is inexpensive and easy to manufacture, especially on an industrial scale.

Advantageously, the OLED device may also be organized in a plurality of substantially parallel light-emitting rows, these rows preferably being spaced apart a distance of less than 0.5 mm, each row being capable of being connected in series.

From one row to another, the electrode zones may be of substantially different shape and/or size.

These rows may preferably be electrically isolated from one another by an isolating resin, especially deposited by screen printing or inkjet printing.

The intrarow spaces and/or the spaces between rows may preferably be manufactured by laser or by chemical screen printing with an etching paste.

The distance between the light-emitting zones of separate rows may be larger than the distance between the zones in a given row, preferably from 100 μm, especially between 100 μm and 250 μm.

Each row may thus be independent. If one of the zones in each row malfunctions, the entire row nevertheless continues to function and adjacent rows remain intact.

Alternatively, the lower electrode may comprise a plurality of rows of lower electrode zones and the light-emitting layer and the upper electrode reproduce these rows (shifted in the direction of the rows). Various types of connection are therefore possible in the case of a plurality of rows:
a single series connection of all the light-emitting zones;
an array of series and parallel connections;
series connections specific to each row.

For a given (single) row connected in series (typically oriented parallel to two opposite edges of the substrate), two US soldering operations may be carried out:
the first US soldering operation being on the (first) lower connection edge, called the “first” lower electrode zone of the row, typically closest a first edge of the substrate; and
the second US soldering operation being on the upper electrical connection zone, which is the zone adjacent the last lower electrode zone of the row, typically closest an edge of the substrate opposite the first edge.

For a plurality of given rows connected in series (each one typically being oriented parallel to two opposite edges of the substrate), it is possible to carry out two US soldering operations per row, as described above, for a series connection.

For a plurality of given rows connected in series/parallel (typically each one in a given direction parallel to two opposite edges of the substrate), two US soldering operations may be carried out:
the first US soldering operation extending over the edges of the “first” lower electrode zones of each row, typically the zones that are closest a first edge of the substrate;
the second US soldering operation extending over the edges of the “last” lower electrode zones of the rows, typically the zones closest an edge of the substrate opposite the first edge.

Moreover, the substrate may preferably be flat. The substrate may be transparent (in particular for emission through the substrate).

Its main faces may be rectangular, square, or even any other shape (round, oval, polygonal, etc.). The substrate may be a substantial size, for example having an area larger than 0.02 m² or even 0.5 m² or 1 m², with an electrode occupying substantially this entire area (all but excepting the structured zones).

The substrate may be rigid, flexible or semiflexible.

The substrate may be made of a plastic, for example polycarbonate, polyethylene terephthalate (PET), polyethylene naphthalate (PEN), or polymethyl methacrylate (PMMA).

The substrate is preferably made of glass, especially soda-lime-silica glass.

OLEDs are generally categorized into two large families depending on the organic material used.

If the organic light-emitting layers are polymers, PLEDs (polymer light-emitting diodes) are spoken of. If the light-emitting layers are small molecule layers, SM-OLEDs (small-molecule organic light-emitting diodes) are spoken of.

An example of a PLED consists of the following multilayer:
a 50 nm-thick layer of poly(2,4-ethylene dioxythiophene) doped with poly(styrenesulfonate) (PEDOT:PSS); and
a 50 nm-thick poly(p-phenylenevinylene) Ph-PPV phenyl layer.

The upper electrode may be a Ca layer.

Generally, the structure of an SM-OLED consists of a stack of a hole injection layer, a hole transport layer, an emissive layer, and an electron transport layer.

An example of a hole injection layer is copper phthalocyanine (CuPC), the hole transport layer may for example be N,N′-bis(naphthalen-1-yl)-N,N′-bis(phenyl)benzidine (α-NPB).

The emissive layer may for example be a layer of fac-tris(2-phenylpyridine)iridium [Ir(ppy)₃]-doped 4,4′,4″-tri(N-carbazolyl)triphenylamine (TCTA).

The electron transport layer may be composed of aluminum tris-(8-hydroxyquinoline) (Alq₃) or bathophenanthroline (BPen).

The top electrode may be a layer of Mg/Al or LiF/Al.

Examples of organic light-emitting multilayers are for example described in document U.S. Pat. No. 6,645,645.

The OLED device according to the invention may moreover incorporate any functionalization(s) known in the glazing field. Among these functionalizations, mention may be made of: hydrophobic/oleophobic layers, hydrophilic/oleophilic layers, photocatalytic antifouling layers, reflective multilayers reflecting thermal (solar control) or infrared (low-E) radiation, antireflection multilayers, and/or a reflective layer providing a mirror effect.

The OLED device according to the invention may form (whether alternatively or cumulatively) a decorative or architectural illuminating system, a signaling or display system—for example for displaying a graphic, logo or alphanumeric sign—whether for indoor or outdoor use.

The OLED device according to the invention may be intended to be used in the construction of buildings, optionally in a double glazing unit, forming curtain walling, especially providing illumination, or a (door) window, especially providing illumination.

The OLED device according to the invention may be intended for use in a means of transportation, as a rear window, a side window, or as an illuminating automobile roof, as a rear view mirror, part of a windshield, a windshield, or in any other land-based, sea-based or air-based vehicle, especially as a porthole or in a cockpit.

The OLED device according to the invention may be intended for use in urban furniture such as bus shelters, in a display cabinet, in a jeweler's display case, a shop window or in a greenhouse.

The OLED device according to the invention may also be intended for interior furnishings, especially being a shelf element, a mirror, an illuminating panel for an item of furnisher, an aquarium wall, a floor tile, in particular an illuminating floor tile, or for use in wall or floor or ceiling coverings.

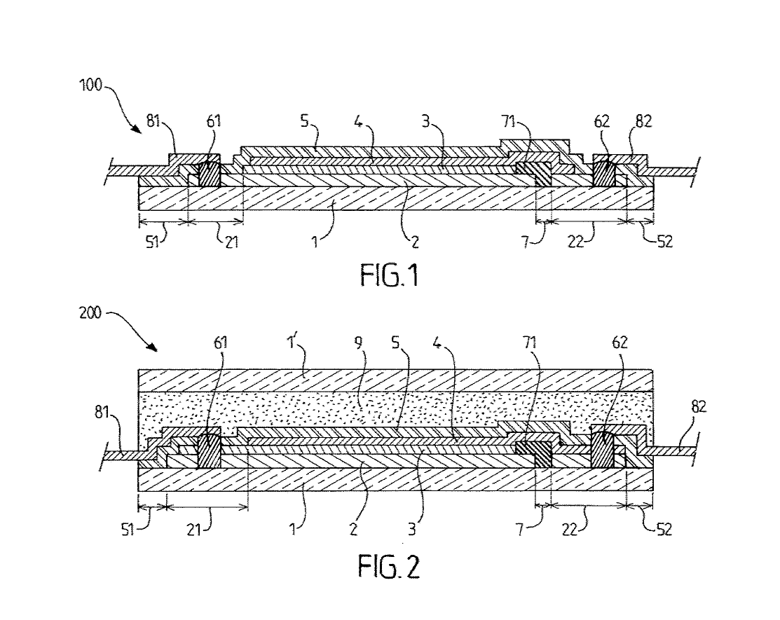

The present invention will be better understood on reading the detailed description below of exemplary nonlimiting embodiments, and of the following FIGS. 1 to 6 which schematically show partial views of various embodiments of OLED encapsulated devices according to the invention.

FIG. 1 is a schematic longitudinal cross-sectional view of an OLED encapsulated device with electrical connections, in a first embodiment of the invention.

FIG. 1a is a schematic partial top view of the OLED encapsulated device in FIG. 1.

FIG. 1b is a schematic partial top view of a variant of the OLED encapsulated device in FIG. 1.

FIG. 2 is a schematic longitudinal cross-sectional view of an OLED encapsulated device with electrical connections, in a second embodiment of the invention.

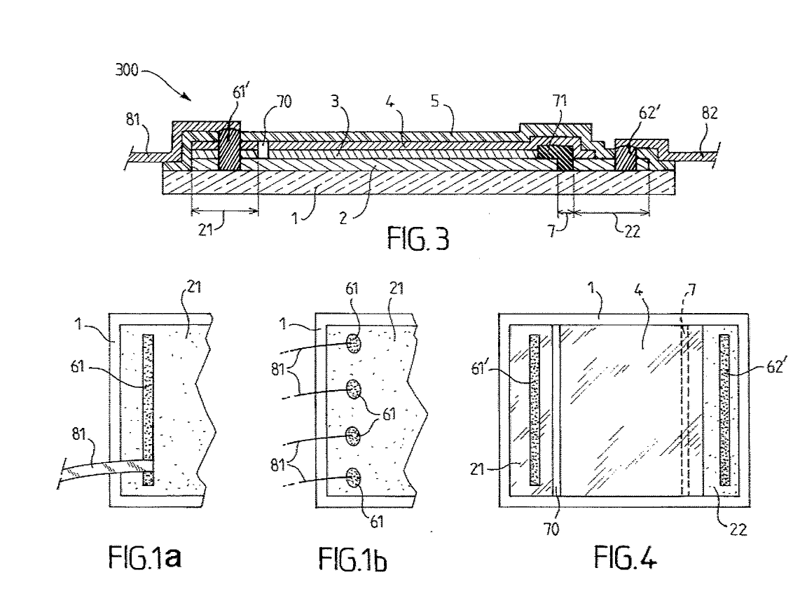

FIG. 3 is a schematic longitudinal cross-sectional view of an OLED encapsulated device with electrical connections, in a third embodiment of the invention.

FIG. 4 is a schematic partial top view of the OLED encapsulated device in FIG. 3.

FIG. 5 is a schematic partial top view of a variant of the OLED encapsulated device in FIG. 3.

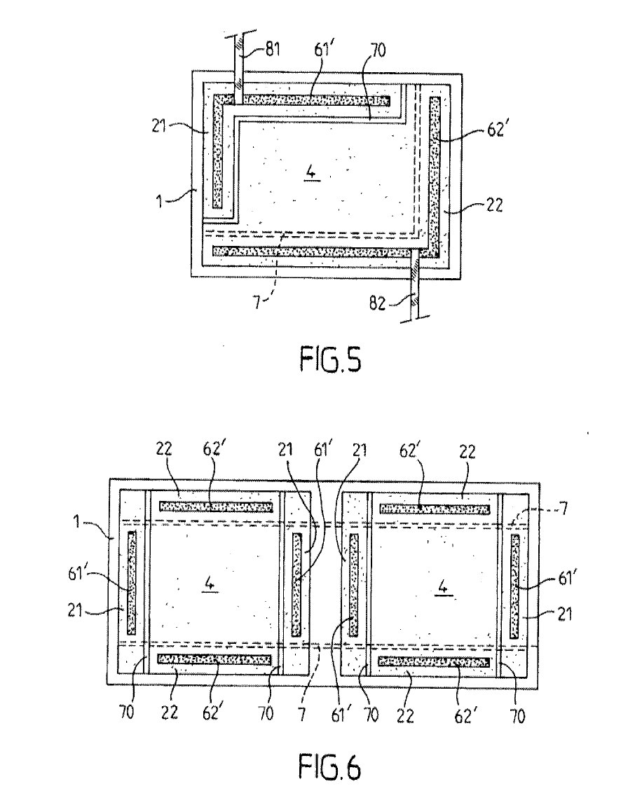

FIG. 6 is a schematic partial top view of another variant of the OLED encapsulated device in FIG. 3.

For the sake of clarity, the various elements of the figures have not been drawn to scale.

### EXAMPLE 1

FIG. 1 is a schematic longitudinal cross-sectional view of an OLED encapsulated device 100 with electrical connections, in a first embodiment of the invention.

The OLED encapsulated device 100 emits through the substrate, and comprises:
a transparent dielectric substrate, for example a glass sheet, for example being rectangular in shape with longitudinal and lateral edges;
a first transparent electrode 2, called the lower electrode, based on one or more electroconductive layers, for example being square in shape, and preferably shifted from the edges of the substrate 1 (in order to limit corrosion, especially in the case of a silver electrode);
an organic light-emitting system 3 based on one or more organic light-emitting layers, located partially on (or as a variant, covering) the lower electrode 2, leaving a first edge 21 of the electrode 2 exposed, here what is called the first lateral edge because it lies along the first lateral edge of the substrate;
a second reflective electrode, called the upper electrode, preferably taking the form of an electroconductive system, located on the organic light-emitting system 3 (for example covering its surface), on one side leaving the lateral edge 21 of the electrode 2 exposed, and on the other side extending onto an adjacent zone, here the lateral zone 22, electrically isolated from the lower electrode 2; furthermore, the upper electrode 4 partially covers a strip-like portion 22 that is made from the material(s) of the lower electrode 2, this strip being shifted from the second lateral edge of the substrate and separated from the lower electrode 2 by an electrically isolating line 7 about 200 μm in width and filled with a passivating resin 71 and furthermore extending onto one superficial edge of the lower electrode 2; and
an electrically insulating encapsulation 5 based on a layer, for example, of 500 nm-thick Si₃N₄ or SiO₂ deposited under vacuum or by an atmospheric-pressure plasma, covering the surface and the edge faces of the upper electrode 4, of the organic light-emitting system 3 and of the lower electrode 2.

The passivating resin 71 is for example an acrylic or polyamide resin, for example the resins Wepelan SD2154 E and SD 2954.

The encapsulation 5 also covers border zones 51, 52 of bare glass, along the first and second lateral edges of the glass 1.

The glass sheet 2 is about 0.7 to 10 mm in thickness, is optionally extraclear glass, and may have an area of about 1 m². Its edge face 21 is preferably smooth. The sheet 2 is optionally thermally or chemically tempered and/or curved.

The lower electrode 2 is, for example, a silver containing thin-film multilayer or even a, preferably planarized, metal mesh.

The organic light-emitting system (OLED) 3 is for example formed from:
a layer of α-NPD;
a layer of TCTA+Ir(ppy)₃;
a layer of BPen; and
a layer of LiF.

The organic light-emitting system 3 may emit polychromatic radiation, which is to say white light.

The reflective upper electrode 4 is made of metal and is especially based on silver or aluminum. For the electrical connections, the OLED device 100 comprises:
a lower connection (US) solder pad 61 that passes through the encapsulation 5 and the lower electrode 2 in a zone of the exposed lateral edge 21; and
an upper connection (US) solder pad 62 that passes through the encapsulation 5 and the upper electrode 4 in the adjacent strip-like zone 22.

The solder pads 61 and 62 protrude from the encapsulation 5. The solder is a tin-based alloy.

Two external connecting elements 81 and 82, extending beyond the lateral edges of the substrate, are respectively soldered directly to the solder plots and 62, US vibration not being required. These solder operations are carried out by local heating of the US solder pads 61, 62, for example with a laser or by induction.

As FIG. 1a shows, the solder pad 61 may extend along a lateral edge and take the form of a strip for better spreading of the current (forming a busbar type current lead), and the external connecting element 81 may be a foil made of tinned copper. The other solder pad (not shown) extends along the opposite lateral edge and takes the form of a strip for better spreading of the current (forming a busbar type current lead), and the external connecting element 81 may also be a foil made of tinned copper

As FIG. 1b shows, the solder pad 61 may extend along the lateral edge and take the form of regularly distributed localized spots of solder for better spreading of the current, and the external connecting element 81 may be a series of tinned copper wires fastened to these localized spots of solder.

The other solder pad (not shown) may extend along the opposite lateral edge and take the form of regularly distributed localized spots of solder for better spreading of the current, and the external connecting element may be a series of tinned copper wires fastened to these localized spots of solder.

The OLED device 100 is produced in the following way:
in a first step, the thin film(s) of lower electrode material(s) are deposited on the substrate 1, for example by evaporation or magnetron sputtering, for example forming a silver containing multilayer or even a planarized metal (aluminum, etc.) mesh, its busbar-type current lead optionally being formed at the same time;
in a second step, the thin film(s) of lower electrode material(s) are structured, preferably by selective acid etching using a screen-printed etching paste or even by laser cutting, in order to form two electrically isolated zones: the lower electrode zone 2 and the adjacent lateral zone 22 for the electrical connection of the upper electrode 4, and the edges of the lower electrode 2 are passivated at least on the same side as the adjacent lateral zone 22. Laser cutting produces characteristic visible beads.
in a third step, the organic light-emitting layers (defining the illuminating zone) are deposited on the lower electrode 2 (leaving uncovered for example the edge zone 21 opposite the passivation zone 7, for the lower connecting zone) and the one or more thin films for the upper electrode 4 are deposited, for example by evaporation, on the organic layers, the passivation layer and (at least) part of the lateral strip 22.
in a fourth step, the one or more encapsulation layers 5 covering the assembly formed by the upper electrode 4, the connecting zone 21 of the lower electrode, and the lateral adjacent zone 22 (if it extends beyond the upper electrode) are deposited.
in a fifth step, ultrasonic soldering is used to form the zone connecting the lower electrode and the zone connecting the upper electrode.
in a sixth step: the foil 71 is soldered to the solder pad 61 and the foil 72 is soldered to the solder pad 62.

### EXAMPLE 2

FIG. 2 is a schematic longitudinal cross-sectional view of a light-emitting encapsulated device 200 with electrical connections, in a second embodiment according to the invention.

The light-emitting encapsulated device 200 firstly differs from the first device 100 in that it furthermore comprises an (EVA, PVB, PU, or silicone, etc.) lamination interlayer 9 or a coat of resin and a glass counter substrate 1′ thereby adding further protection to the encapsulation 5.

The lamination interlayer 9 for example bears external connecting elements 71, 72.

The light-emitting encapsulated device 200 then differs from the first device 100 in that the organic light-emitting system 3 extends into the lateral edge zone i.e. the lower connecting zone 21. Thus, the US solder pad 61 also passes through this system 3 in this zone 21.

The light-emitting encapsulated device 200 lastly differs from the first device 100 in that the upper electrode 4 extends further and covers all the lower electrode materials in the adjacent zone 22, i.e. in the upper connecting zone. Thus the US solder pad 62 also passes through the upper electrode 4 in this zone 22.

### EXAMPLE 3

FIG. 3 is a schematic longitudinal cross-sectional view of a light-emitting encapsulated device 300 with electrical connections, in a second embodiment according to the invention.

The light-emitting encapsulated device 300 differs from the first device 100 above all in that the organic light-emitting system 3 and the upper electrode 4′ (substantially) cover the lower electrode 4 in the lateral edge zone 21 i.e. the lower connecting zone 21. Thus, the lower connecting US solder pad 61′ also passes through these layers.

Furthermore, to prevent short-circuits, the device 300 comprises an electrically isolating zone 70 that is more central than this solder pad 61′, which zone at least separates the upper electrode 4, and preferably also the organic light-emitting system 3, into two zones. Preferably, this selective electrical isolation zone is produced by laser cutting, and preferably before encapsulation 5. As a variant, this selective isolation zone is produced by laser cutting after encapsulation and lamination is carried out.

As for the lower electrode 2, it remains intact or sufficiently well preserved by this structuring to conduct electricity in this region.

This electrically isolating zone 70 may be filled with a passivating resin, for example identical to the resin 71, or even filled by the encapsulation. This electrically isolating zone 70 is in any case covered by the encapsulation 5.

In this embodiment, it may also be preferable to use a laser to form the isolation zone 7.

As shown in FIG. 4, the solder pads 61′, 62′ and the isolation zones 70 and 7 are lateral strips, for example parallel lateral strips.

The light-emitting encapsulated device 300 may optionally differ from the first device 100 in that it also (even only) emits via its frontside (via the upper electrode 4 and encapsulation layer 5). Thus, the upper electrode 4′ and the encapsulation 5 are transparent and the lower electrode 1′ is reflective (or even semireflective).

FIG. 5 is a partial schematic top view of a variant of the OLED encapsulated device in FIG. 3.

The solder pads 61′, 62′ each lie along a lateral and longitudinal edge, at right angles.

The isolation zones 70 and 7 are modified accordingly.

FIG. 6 is a partial schematic top view of another variant of the OLED encapsulated device in FIG. 3.

There are two illuminating OLED zones, and for each of these:
two discontinuous strip-like US solder pads 61′ on the lateral edges 21 of the OLED zone in question, in order to form two opposed lower connecting zones;
two discontinuous strip-like US solder pads 62′ on the lateral edges 22 of the OLED zone in question, in order to form two opposed upper connecting zones;
two selective electrical isolation zones 70 along the lateral edges 21, in a straight line; and
two electrical isolation zones 7 along the longitudinal edges 22, in a straight line.

To shorten manufacture, it is preferable to simply form two electrical isolation lines 7 serving for the two active zones.

The OLED devices described above have many applications.

The light-emitting devices 100 to 300 may be intended for architectural applications, thus forming illuminating curtain walling, windows or glass doors.

The devices 100 to 300 may be intended for use in a means of transportation, as an illuminating rear window, an illuminating side window, or as an illuminating automobile roof, as a rear view mirror, part of a windshield, or in any other land-based, sea-based or air-based vehicle, especially as a porthole or in a cockpit.

The light-emitting devices 100 to 300 may be intended for use in urban furniture such as bus shelters, in a display cabinet, in a jeweler's display case, in a shop window, in a shelf element, in an aquarium wall or in a greenhouse.

The light-emitting devices 100 to 300 may be intended for interior furnishings, forming an illuminating panel for an item of furnisher, or an illuminating floor tile, especially a glass floor tile, or may be intended for use in wall or floor coverings, as illuminating ceiling tiles or as a splashback for a kitchen or bathroom.

The light-emitting devices 100 to 300 may provide illumination for a decorative, architectural, signaling or display purpose.

1. A process for making one or more electrical connections to an organic light-emitting diode containing encapsulated device comprising
a dielectric substrate;
a first electrode including one or more electroconductive layers;
an organic light-emitting system including one or more organic light-emitting layers, located on the first electrode;
a second electrode including one or more electroconductive layers, located on the organic light-emitting system and optionally extending onto an adjacent zone that is electrically isolated from the lower electrode;
an a dielectric encapsulation layer, covering the second electrode, the organic light-emitting system and the first electrode, the process comprising, after encapsulation of the device:
a step of ultrasonic soldering at a first edge of the first electrode to form a lower electrical connection zone, the solder forming, via local deterioration, a solder pad extending from an encapsulation surface as far at least as a surface of the first electrode;
and/or
ultrasonic soldering in the adjacent zone, which is electroconductive and forms an upper electrical connection zone, the solder forming, via local deterioration, a solder pad extending from the encapsulation surface as far at least as the surface of the second electrode.

2. The process for making one or more electrical connections to an organic light-emitting diode containing encapsulated device as claimed in claim 1 comprising forming a current lead for the first electrode subjacent the dielectric encapsulation layer, which is optionally coupled with forming the first electrode, and which comprises the deposition of one or more materials for the first electrode.

3. The process for making one or more electrical connections to an organic light-emitting diode containing encapsulated device as claimed in claim 1 wherein said process is exempt from any forming of internal current leads for the first electrode and/or for the second electrode, before said encapsulation.

4. The process for making one or more electrical connections to an organic light-emitting diode containing encapsulated device as claimed in claim 1 wherein said process is exempt from any forming of current leads for the first electrode and/or for the second electrode in a zone without said encapsulation layer, after said encapsulation.

5. The process for making one or more electrical connections to an organic light-emitting diode containing encapsulated device as claimed in claim 1 wherein the solder resulting from the soldering for the lower electrical connection is sufficiently extensive to spread current and/or the solder resulting from the soldering for the upper electrical connection is sufficiently extensive to spread current.

6. The process for making one or more electrical connections to an organic light-emitting diode containing encapsulated device as claimed in claim 1 comprising connecting an external connecting element for the first electrode by heating the encapsulated device in the lower electrical connection zone after the soldering or during said soldering for the lower electrical connection zone and/or comprising connecting an external connecting element for the second electrode by heating the encapsulated device in the upper electrical connection zone after the soldering or during said soldering for the upper electrical connection zone.

7. The process for making one or more electrical connections to an organic light-emitting diode containing encapsulated device as claimed in claim 1 wherein the deposition of the one or more layers for the second electrode leaves exposed the first edge optionally coated with the one or more organic light-emitting layers or wherein, the layer deposition for the second electrode covering said first edge, the process comprising, preferably before said soldering in the lower electrical connection zone and especially before encapsulation, a selective local structuring, without masking, in the zone of the first edge, which divides said layer deposition for the second electrode into an electrically inactive zone and into said second electrode, especially structuring by chemical etching, laser ablation, mechanical cutting and wherein preferably the process comprises filling the structured zone with an insulating material.

8. The process for making one or more electrical connections to an organic light-emitting diode containing encapsulated device as claimed in claim 1 wherein before depositing the second electrode, the process comprises locally structuring of said one or more layers of the first electrode without (post-) masking, especially by laser ablation, chemical etching, mechanical cutting.

9. An organic light-emitting diode containing encapsulated device with one or more electrical connections, comprising:
a dielectric substrate;
a first electrode including one or more electroconductive layers;
an organic light-emitting system including one or more organic light-emitting layers, located on the first electrode;
a second electrode including one or more electroconductive layers, located on the organic light-emitting system and optionally extending onto an adjacent zone that is electrically isolated from the first electrode;
an a dielectric encapsulation including one or more layers, covering the second electrode, the organic light-emitting system and the first electrode;
at a first edge of the first electrode, a lower electrical connection zone formed from a solder pad making contact with the first electrode and opening out of the encapsulation; and/or
in the adjacent zone, which is electroconductive and electrically isolated from the first electrode, an upper electrical connection zone formed from a solder pad, which solder pad opens out of the encapsulation.

10. The organic light-emitting encapsulated device with one or more electrical connections as claimed in claim 9, wherein the second electrode covers the first edge of the first electrode and wherein the device comprises a zone of selective electrical isolation between the lower electrical connection and the upper electrical connection, the zone separating the second electrode into two parts.

11. The organic light-emitting encapsulated device with one or more electrical connections as claimed in claim 10 wherein the zone of selective electrical isolation is a cut, especially produced by laser cutting.

12. The organic light-emitting encapsulated device with one or more electrical connections as claimed in claim 9, wherein the second electrode does not cover the first edge of the first electrode.

13. The organic light-emitting encapsulated device with one or more electrical connections as claimed in claim 9, wherein the first electrode is a thin-film multilayer comprising at least one thin silver-based film and the dielectric encapsulation covers the edge face of the first electrode.

14. The organic light-emitting encapsulated device with one or more electrical connections as claimed in claim 9, wherein in the adjacent zone, the one or more electroconductive layers are identical to the one or more electroconductive layers of the first electrode, and are electrically isolated from the first electrode by cutting, especially laser cutting.

15. The organic light-emitting encapsulated device with one or more electrical connections as claimed in claim 9, comprising an external connecting element for the first electrode connected, especially by soldering, to the solder pad and/or an external connecting element for the second electrode connected, especially by soldering, to the solder pad.

16. The process for making one or more electrical connections to an organic light-emitting diode containing encapsulated device as claimed in claim 1, wherein the dielectric encapsulation layer includes a plurality of layers.
